(19) United States
(12) Patent Application Publication
(10) Pub. No.: US 2016/0295735 A1
(43) Pub. Date: Oct. 6, 2016

(54) EXPANSION CARD SECUREMENT STRUCTURE FOR INDUSTRIAL COMPUTER AND SECUREMENT LATCH THEREOF

(71) Applicant: AIC INC., Taoyuan Hsien (TW)

(72) Inventor: Yu-Feng LIN, Taoyuan Hsien (TW)

(21) Appl. No.: 14/674,455

(22) Filed: Mar. 31, 2015

(51) Int. Cl. H05K 7/14; H05K 5/02

(52) U.S. Cl. CPC H05K 7/1429; H05K 5/0221

(57) ABSTRACT

An expansion card securement structure for an industrial computer, for securing an expansion card onto an industrial computer, includes a wall plate and a securement latch. The wall plate on the industrial computer includes an expansion slot for receiving expansion card, an insertion hole near the expansion slot, a through hole near the expansion slot. The securement latch includes a main body, a pivotal axle at middle of the main body, a pressing plate on one end of the main body and an elastic arm on another end thereof, and a latch hook on the elastic arm. The pivotal axle is attached near the expansion slot, the securement latch penetrates the through hole, the elastic arm and the pressing plate at opposite sides of the wall plate, the securement latch rotates to the pressing plate for pressing the expansion card, and the latch hook hooked onto the through hole.

### BACKGROUND OF THE INVENTION

1. Field of the Invention

The present invention is related to an expansion card securement mechanism for an industrial computer, in particular, to an expansion card securement structure for an industrial computer and a securement latch thereof.

2. Description of Related Art

A typical industrial computer is installed with a large amount of expansion cards to satisfy the needs of the uses thereof, and the expansion cards can be, such as, a video card, a network card, a storage medium or a server host machine and so on. In a known prior art, when there is a need to secure the expansion card, in addition to the use of the gold finger portion of the expansion card for inserting into the industrial computer to partially provide the securement effect, there is also a need to utilize screws for fastening the metal piece of the expansion card onto the chassis of the industrial computer such that it can be completely secured. However, such utilization of screws for securement requires the use of extra tools, such as a screw driver, in order to secure or detach the interface card. Furthermore such type of installation method is relatively more time consuming in practice.

In view of the above, the inventor seeks to overcome the problems associated with the currently existing technique after years of research and development along with the utilization of theoretical principles, and it is an objective of the inventor to provide a reasonable design and an improvement capable of effectively solve the aforementioned problems.

### SUMMARY OF THE INVENTION

The present invention provides an expansion card securement structure of an industrial computer and a securement latch thereof.

The present invention provides a securement latch, comprising a main body, a pivotal axle, a pressing plate and an elastic arm. The main body is of an elongated shape, the pivotal axle is formed on a middle section of the main body, a pressing plate is formed on one end of the main body, the elastic arm is formed on another end of the main body and includes a latch hook formed on the elastic arm.

Preferably, the elastic arm extends to turn to a reverse direction. The elastic arm includes a blocking wall formed corresponding to the latch hook and arranged spaced apart from the latch hook. An angle is formed between the pressing plate and the main body.

The present invention further provides an expansion card structure for an industrial computer, used for securing an expansion card onto an industrial computer, comprising a wall plate and a securement latch. The wall plate is arranged on the industrial computer, the wall plate includes an expansion slot formed on the wall plate and is provided for the expansion card to be inserted therein, an insertion slot is formed on one end adjacent to the expansion slot, a through hole is formed on another end adjacent to the expansion slot. The securement latch comprises an elongated main body, a pivotal axle formed at a middle section of the main body, a pressing plate formed on one end of the main body and an elastic arm formed on another end of the main body, and a latch hook formed on the elastic arm. The pivotal axle is pivotally attached adjacent to another end of the expansion slot, the securement latch penetrates through the through hole and the elastic arm and the pressing plate are oppositely positioned at two sides of the wall plate, the securement latch is configured to pivotally rotate along the pivotal axle to the pressing plate in order to press onto the expansion card and the latch hook hooks onto an inner edge of the through hole.

Preferably, the elastic arm extends to turn to a reverse direction. The elastic arm includes a blocking wall formed corresponding to the latch hook and arranged spaced apart from the latch hook. An angle is formed between the pressing plate and the main body.

Preferably, an outer edge of the wall plate includes a position protruding edge formed thereon, and the main body of the securement latch includes a cut-out slot formed corresponding to the position protruding edge.

The expansion card securement mechanism for an industrial computer of the present invention includes the securement latch configured to be pivotally rotated to allow the pressing plate to press onto the expansion card in order to secure the expansion card onto the industrial computer. Furthermore, the elastic arm can be pressed to release the securement latch while pushing the securement latch to pivotally rotate simultaneously in order to release the expansion card. In addition, the latch hook on the elastic arm and the blocking wall can secure the securement latch such that it cannot be pivotally rotated. Therefore, the expansion card is secured onto the industrial computer; as a result, the expansion card securement structure of the present invention is able to firmly secure the expansion card and to facilitate the detachment of the expansion card with ease.

### BRIEF DESCRIPTION OF DRAWING

FIG. 1 is a perspective view of an expansion card securement structure for an industrial computer according to a preferred embodiment of the present invention;

FIG. 2 is a perspective view of the securement latch in a preferred embodiment of the present invention;

FIG. 3 is an illustration showing a securement state of the expansion card securement structure for an industrial computer according to a preferred embodiment of the present invention;

FIG. 4 is another illustration showing a securement state of the expansion card securement structure for an industrial computer according to a preferred embodiment of the present invention;

FIG. 5 is an illustration showing the securement latch of the expansion card securement structure for an industrial computer according to a preferred embodiment of the present invention;

FIG. 6 is an illustration showing a release state of the expansion card securement structure for an industrial computer according to a preferred embodiment of the present invention; and

FIG. 7 is another illustration showing a release state of the expansion card securement structure for an industrial computer according to a preferred embodiment of the present invention.

### DETAILED DESCRIPTION OF THE INVENTION

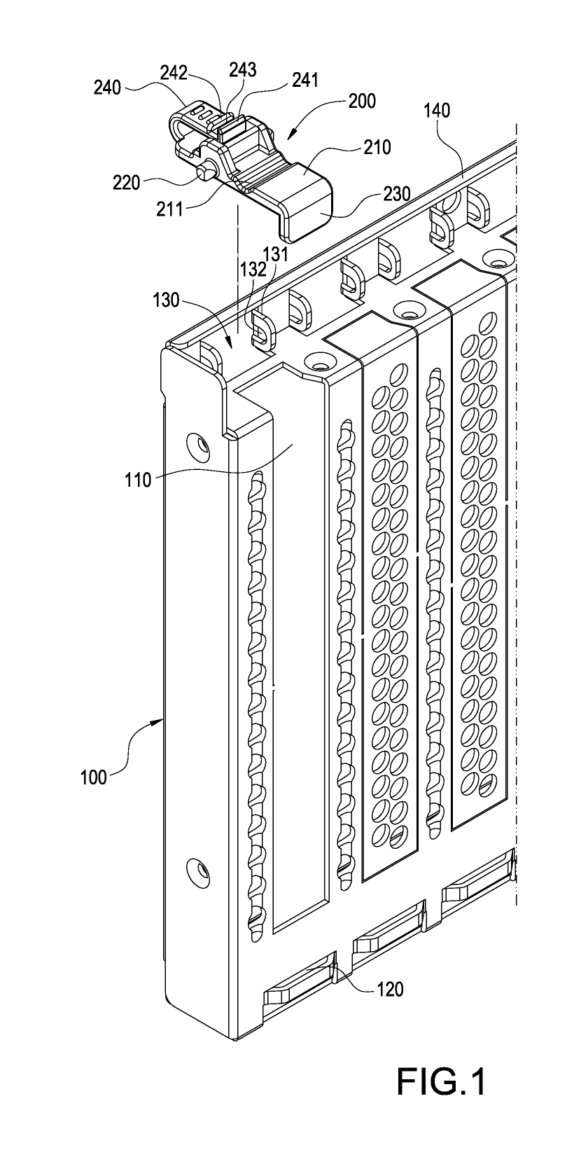

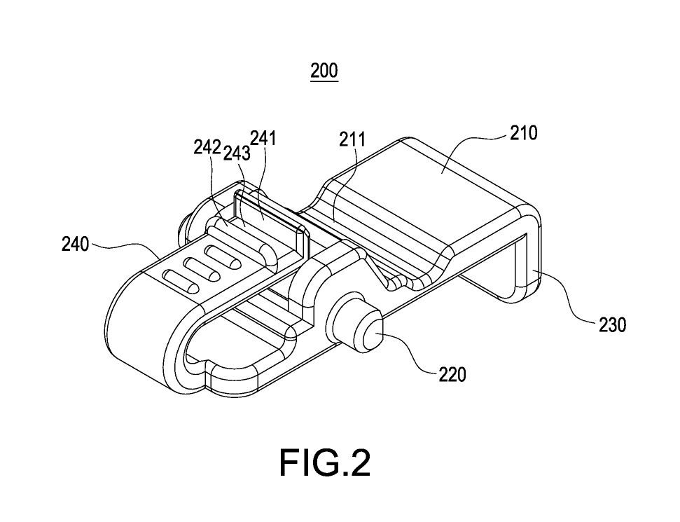

Please refer to FIG. 1 to FIG. 3. According to a preferred embodiment of the present invention, an expansion card securement structure for an industrial computer is provided and is used for securing at least one expansion card 10 onto an industrial computer (not shown in the figures). The expansion card securement structure for an industrial computer of the present invention comprises a wall plate 100 and a securement latch 200.

The wall plate 100 is arranged on the industrial computer; the wall plate 100 includes at least one expansion slot 110 formed thereon, and an insertion hole 120 and a through hole 130 are respectively formed corresponding to the expansion slot 110. In this embodiment, the wall plate 100 includes a plurality of expansion slots 110 arranged parallel in rows adjacent to each other, and an insertion hole 120 and a through hole 130 are respectively formed corresponding to each one of the expansion slots 110. Each one of the expansion slots 110 is provided for an expansion card 10 to be inserted therein respectively. Each one of the insertion hole 120 is arranged adjacent to one of the ends of the corresponding expansion slot 110, and the plurality of insertion slots 120 are preferably arranged on one identical end of the plurality of expansion slots 110 in order to form a row arrangement. The through hole 130 is arranged adjacent to another end of the corresponding expansion slot 110. An inner edge of each one of the through holes 130 includes a pair of protruding ears 131 extended therefrom respectively, and each one of the protruding ears 131 includes a pivotal attachment hole 132 formed thereon respectively. An outer edge of the wall plate includes a position protruding edge 140 formed thereon.

The securement latch 200 is an elastic material, such as rubber or silicon but the present invention is not limited to such types only, integrally formed as one single piece, which comprises a main body 210, and the main body 210 includes a pair of pivotal axle 220, a pressing plate 230 and an elastic arm 240 formed thereon. In this embodiment, the main body 210 is preferably of a flat elongated shape; however, the present invention is not limited to any particular outer shapes of the main body 210. The pair of pivotal axles 220 is formed at a middle section of the main body 210 and arranged oppositely at two sides of the main body 210. The pressing plate 230 is formed on one end of the main body 210 and an angle is preferably formed between the pressing plate 230 and the main body 210; however, the present invention is not limited to any particular degrees of the angle. In this embodiment, the pressing plate 230 extends from the main body 210 and is bent to extend perpendicularly to the main body 210. The elastic arm 240 is formed on another end of the main body 210. The elastic arm 240 extends to turn in a reverse direction in order to form a U shape and is arranged spaced apart from the main body. In addition, the elastic arm 240 includes a latch hook 241 and a blocking wall 242 formed corresponding to the latch hook 241; the latch hook 241 and the blocking wall 242 are preferably arranged spaced apart from each other in order to form a clamping slot 243 between the two. The pair of pivotal axles 220 is pivotally attached to the corresponding pivotal attachment hole 132 and the elastic arm 240 is arranged inside the through hole 130. The securement latch 200 penetrates through the through hole 130 and the elastic arm 240 and the pressing plate 230 are arranged oppositely at two sides of the wall plate 100, and the securement latch 200 is able to pivotally rotate along the pivotal axle 220. The main body 210 of the securement latch 200 includes a cut-out slot 211 formed thereon and corresponding to the position protruding edge 140 of the wall plate 100; the cut-out slot 211 is used for receiving the position protruding edge 140 such that when the securement latch 200 is rotated to the position protruding edge 140 inside the cut-out slot 211, such configuration can be utilized to restrict the pivotal rotation amount of the securement latch 200 accordingly.

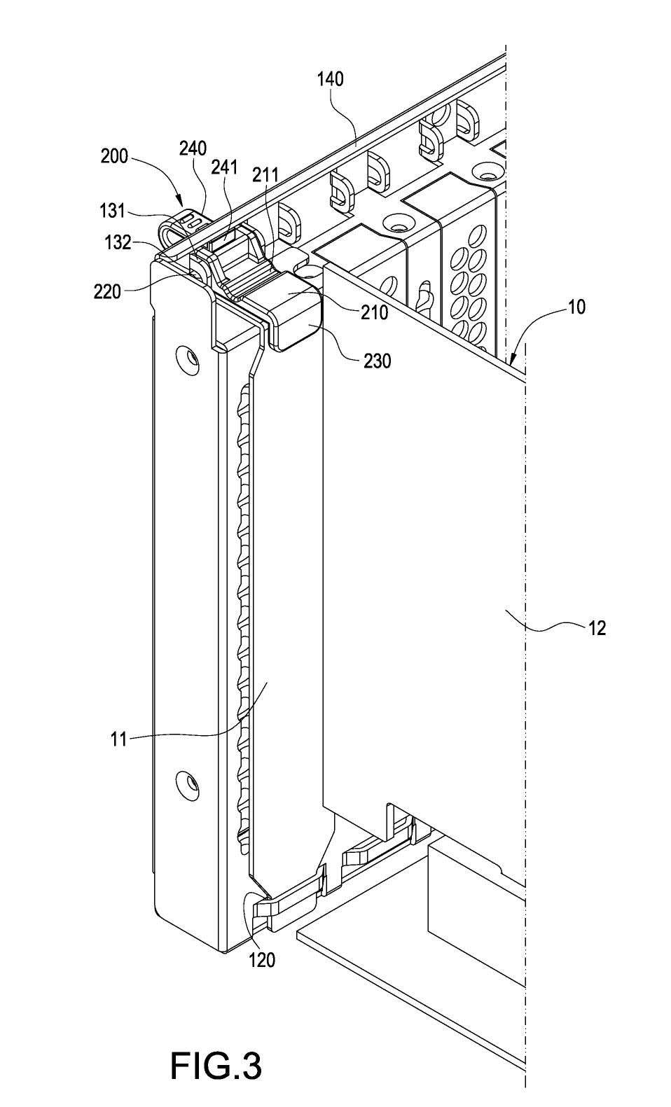

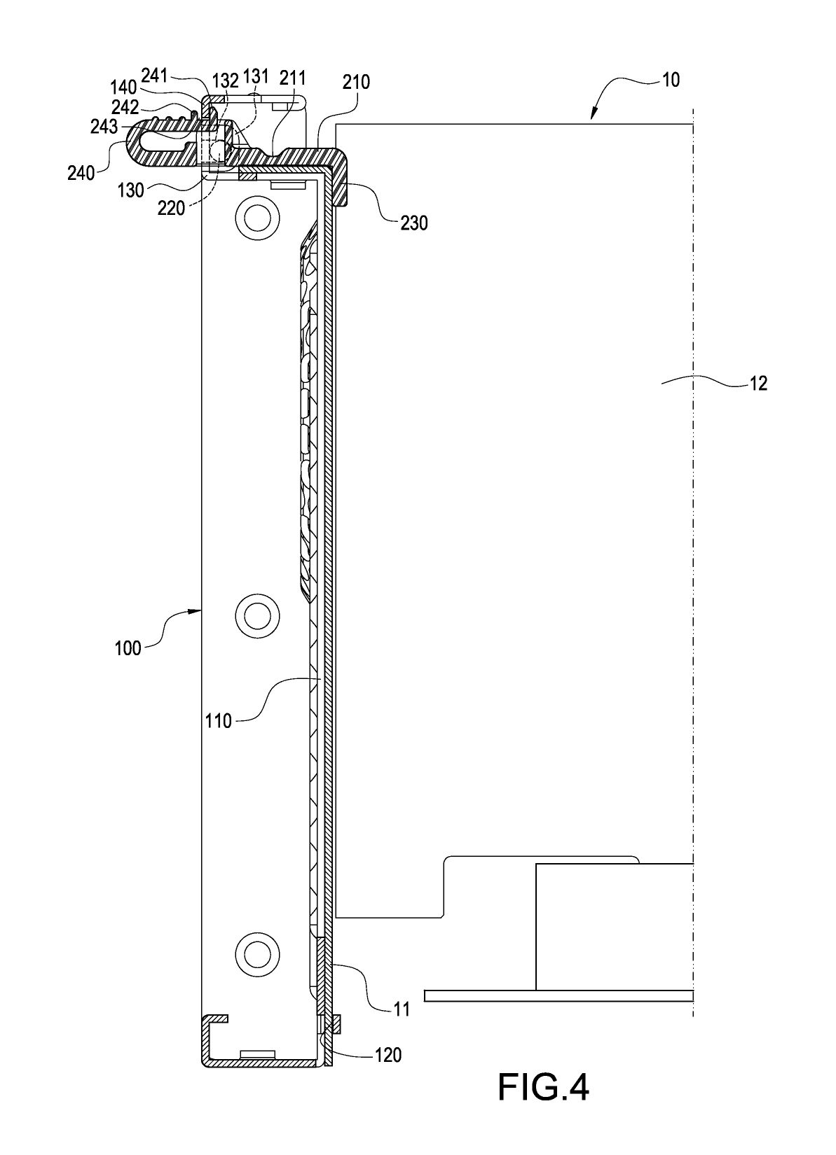

Please refer to FIG. 3 and FIG. 4. The expansion card 10 includes a side plate 11 and a circuit board 12 perpendicular to the side plate 11, and the circuit board 12 may include a transmission port (not shown in the figures) electrically connected to the circuit board 12; the side plate 11 is preferably a metal plate and is preferably of an elongated shape. The expansion card 10 can be peripheral component interconnect (PCI) interface. When the expansion card 10 is installed onto the industrial computer, the side plate 11 is configured corresponding to the expansion slot 110 in order to allow the transmission portion to be inside the expansion slot 110, and one end of the side plate 11 is inserted and secured into the insertion hole 120. The securement latch 200 is able to pivotally rotate along the pivotal axle 220 to the pressing plate 230 to press onto another end of the side plate 11 of the expansion card 10 in order to secure the side plate 11 onto the wall plate 100. The latch hook 241 on elastic arm 240 is hooked onto the inner edge of the through hole 130 and the inner edge of the through hole 130 is clamped inside the clamping slot 243 formed between the latch hook 241 and the blocking wall 242 in order to secure the securement latch 200 to prevent it from rotating pivotally. As a result, the expansion card 10 is secured onto the industrial computer.

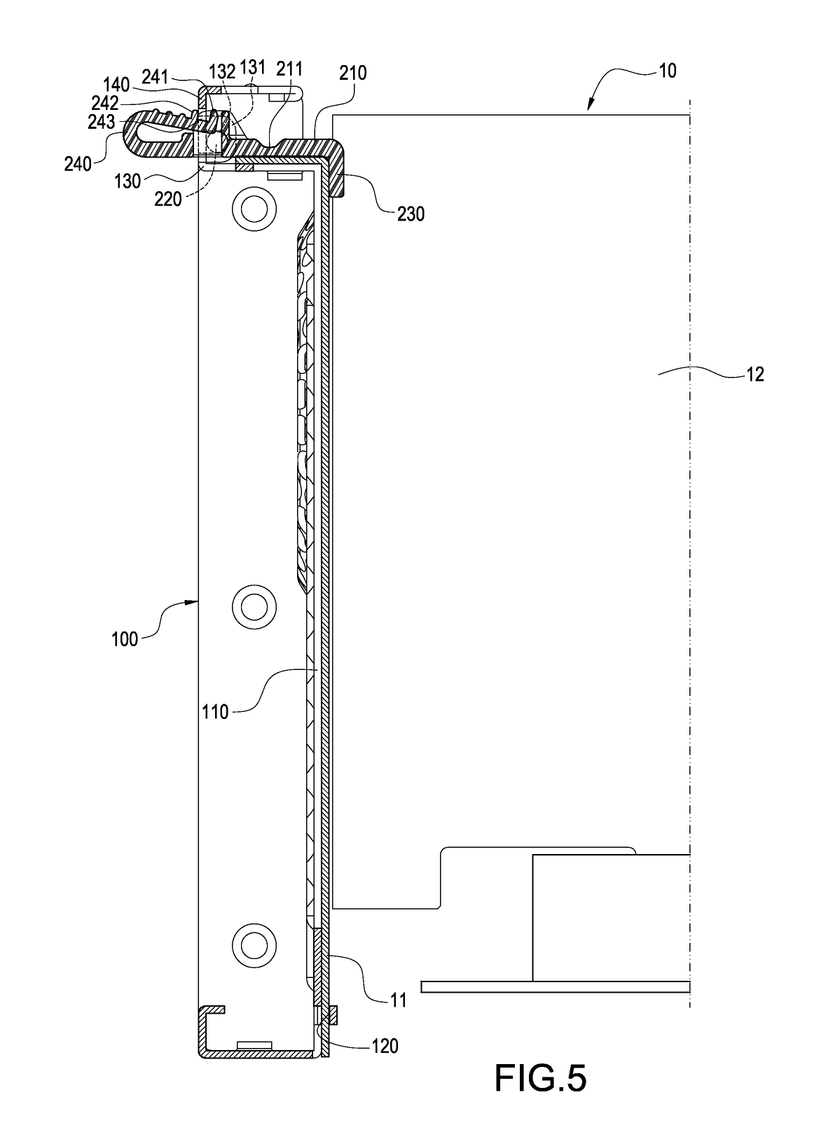

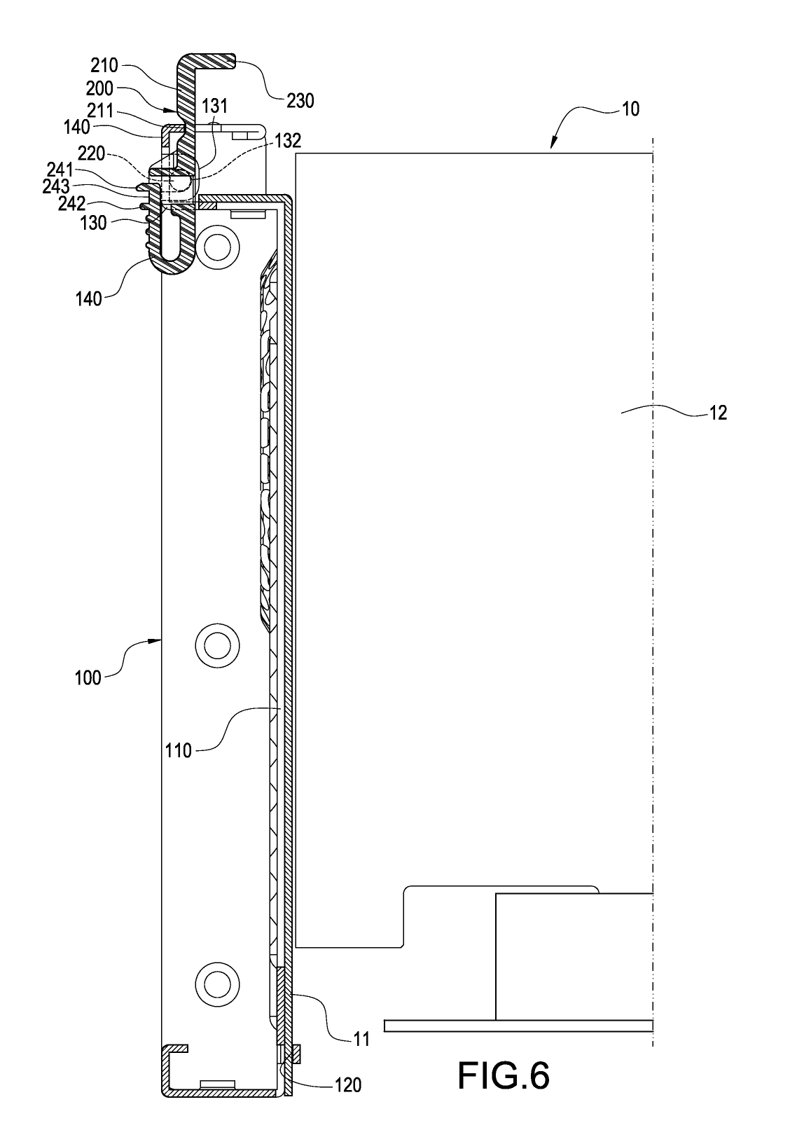

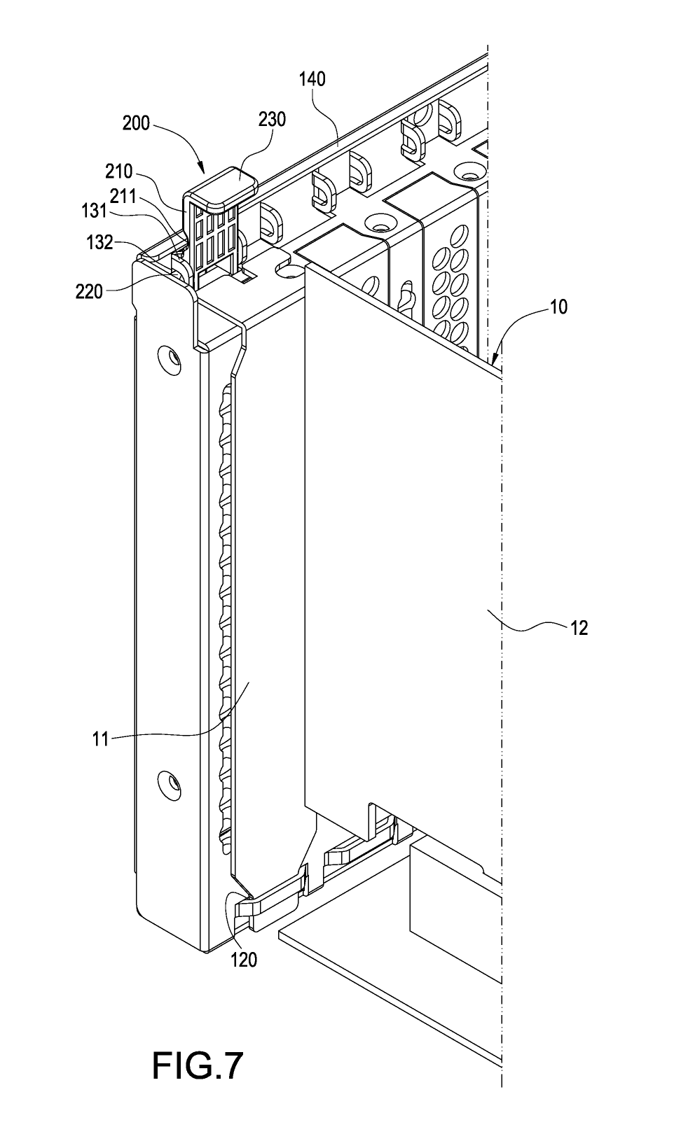

Please refer to FIG. 5 and FIG. 6. When the expansion card 10 is to be removed from the industrial computer, the elastic arm 240 can be pushed toward the main body 210 such that the securement latch 200 is disengaged from the inner edge of the through hole 130 in order to rotate pivotally. Please refer to FIG. 6 and FIG. 7, since the elastic arm 240 and the pressing plate 230 are respectively arranged on two sides of the wall plate 100, during the time when the elastic arm 240 is pushed, a torque is also exerted onto the securement latch 200 simultaneously in order to allow it to rotate pivotally. By pivotally rotating the securement latch 200, the pressing plate 230 is disengaged from the side plate 11 of the expansion card 10; therefore, the expansion card 10 is then released.

In view of the above, it shall be noted that the above description provides preferred embodiments of the present invention only, which shall not be treated as limitation of the scope of the present invention. Any equivalent techniques and technical modifications based on the content of the specification and drawings of the present invention shall be deemed to be within the scope of the present invention.

What is claimed is:

1. A securement latch, comprising:
a main body having an elongated shape;
a pivotal axle formed on a middle section of the main body;
a pressing plate formed on one end of the main body; and
an elastic arm formed on another end of the main body and having a latch hook formed on the elastic arm.

2. The securement latch according to claim 1, wherein the elastic arm extends to turn to a reverse direction.

3. The securement latch according to claim 2, wherein the elastic arm is of a U shape

4. The securement latch according to claim 1, wherein the elastic arm includes a blocking wall formed corresponding to the latch hook and arranged spaced apart from the latch hook.

5. The securement latch according to claim 1, wherein an angle is formed between the pressing plate and the main body.

6. An expansion card structure for an industrial computer, used for securing an expansion card onto an industrial computer, comprising:
a wall plate arranged on the industrial computer, the wall plate having an expansion slot formed on the wall plate and provided for the expansion card to be inserted therein, an insertion slot formed on one end adjacent to the expansion slot, a through hole formed on another end adjacent to the expansion slot; and
a securement latch comprising an elongated main body, a pivotal axle formed at a middle section of the main body, a pressing plate formed on one end of the main body and an elastic arm formed on another end of the main body, and a latch hook formed on the elastic arm;
wherein the pivotal axle is pivotally attached adjacent to another end of the expansion slot, the securement latch penetrates through the through hole and the elastic arm and the pressing plate are oppositely positioned at two sides of the wall plate, the securement latch is configured to pivotally rotate along the pivotal axle to the pressing plate in order to press onto the expansion card and the latch hook hooks onto an inner edge of the through hole.

7. The expansion card securement structure according to claim 6, wherein the elastic arm extends to turn to a reverse direction.

8. The expansion card securement structure according to claim 7, wherein the elastic arm is of a U shape

9. The expansion card securement structure according to claim 6, wherein the elastic arm includes a blocking wall formed corresponding to the latch hook and arranged spaced apart from the latch hook, and the latch hook cooperates with the blocking wall to clamp onto the inner edge of the through hole.

10. The expansion card securement structure according to claim 6, wherein an angle is formed between the pressing plate and the main body.

11. The expansion card securement structure according to claim 6, wherein an outer edge of the wall plate includes a position protruding edge formed thereon, and the main body of the securement latch includes a cut-out slot formed corresponding to the position protruding edge.
